(19) United States
(12) Patent Application Publication
(10) Pub. No.: US 2020/0328271 A1
(43) Pub. Date: Oct. 15, 2020

(54) METAL INSULATOR METAL (MIM) CAPACITORS

(71) Applicant: SEMICONDUCTOR COMPONENTS INDUSTRIES, LLC, Phoenix, AZ (US)

(72) Inventors: Jeffrey Peter GAMBINO, Gresham, OR (US); David T. PRICE, Gresham, OR (US); Akihiro HASEGAWA, Aizuwakamatsu (JP); Derryl ALLMAN, Camas, WA (US); Sallie J. HOSE, Gresham, OR (US); Kenneth Andrew BATES, Happy Valley, OR (US); Gregory Frank PIATT, Sandy, OR (US)

(73) Assignee: SEMICONDUCTOR COMPONENTS INDUSTRIES, LLC, Phoenix, AZ (US)

(21) Appl. No.: 16/506,040

(22) Filed: Jul. 9, 2019

Related U.S. Application Data
(60) Provisional application No. 62/831,305, filed on Apr. 9, 2019.

(51) Int. Cl. H01L 49/02; H01L 23/522; H01L 27/146; H01L 21/3213; H01L 21/321

(52) U.S. Cl. CPC H01L 28/75; H01L 23/5223; H01L 21/3212; H01L 27/14609; H01L 21/32134; H01L 23/5226

(57) ABSTRACT

Implementations of capacitors may include: a first electrode having a first side and a second side. The capacitor may also include a silicon nitride (SiN) layer including on the second side of the first electrode. An opening may be included in the silicon nitride layer. The capacitors may include a dielectric layer within the opening of the SiN layer. The dielectric layer may include a recess. The capacitor may also include a second electrode having a first side and a second side. The first side of the second electrode may be included within the recess of the dielectric layer.

### CROSS REFERENCE TO RELATED APPLICATIONS

This application claims the benefit of the filing date of U.S. Provisional Patent Application 62/831,305, entitled “METAL INSULATOR METAL (MIM) CAPACITORS” to Price et al., which was filed on Apr. 9, 2019, the disclosure of which is hereby incorporated entirely herein by reference.

### BACKGROUND

### 1. Technical Field

Aspects of this document relate generally to capacitors, such as capacitors in semiconductor devices. More specific implementations involve capacitors used in pixels and in stacked image sensors.

### 2. Background

Stacked image sensors with high dynamic range or with global shutter use one or two high capacitance density capacitors per pixel. Various capacitors use a dielectric to store charge in the capacitors for use in an electrical circuit.

### SUMMARY

Implementations of capacitors may include: a first electrode having a first side and a second side. The capacitor may also include a silicon nitride (SiN) layer including on the second side of the first electrode. An opening may be included in the silicon nitride layer. The capacitors may include a dielectric layer within the opening of the SiN layer. The dielectric layer may include a recess. The capacitor may also include a second electrode having a first side and a second side. The first side of the second electrode may be included within the recess of the dielectric layer.

Implementations of capacitors may include one, all, or any of the following:

The dielectric layer may include aluminum oxide.

The second electrode may include titanium nitride (TiN).

The capacitor may further include a layer of tantalum nitride (TaN) between the first electrode and the dielectric layer.

The first electrode may include TiN on Al.

The second electrode may include a first layer of Al and a second layer of TiN.

The first electrode may be coupled to two or more vias.

The first electrode and the second electrode may both include TiN.

The electrode may further include the dielectric layer covering one or more edges of the second electrode.

Implementations of capacitors may include: a substrate having a first side and a second side and a first electrode on the second side of the substrate. The capacitor may also include a silicon nitride (SiN) layer having an etch stop and a dielectric layer may be located in and around the etch stop. The capacitor may include a second electrode over the dielectric layer. The capacitor may be encapsulated in an interlayer dielectric material.

Implementations of capacitors may include one, all, or any of the following:

The dielectric layer may include aluminum oxide.

The second electrode may include titanium nitride (TiN).

The capacitor may further include a layer of tantalum nitride (TaN) between the first electrode and the dielectric layer.

The capacitor may further include the dielectric layer covering one or more edges of the second electrode.

Implementations of semiconductor devices may include: a substrate having a first side and a second side and a first capacitor on the second side of the substrate. The first capacitor may include a first electrode on the second side of the substrate. The first electrode may have a first side and a second side. The first electrode may also include a silicon nitride (SiN) film on the second side of the first electrode. A dielectric layer may be included on the SiN film and a second electrode may be included on the dielectric layer. The semiconductor device may also include a second capacitor on the second side of the substrate. The second capacitor may include a first electrode and a second electrode. The first electrode may have a first side and a second side. A silicon nitride (SiN) layer may be included on the second side of the first electrode. The layer of SiN may have an opening. The second capacitor may include a dielectric layer within the opening of the SiN layer and the dielectric layer may include a recess. The second electrode of the second capacitor may also include a first side and a second side. The first side of the second electrode may be included within the recess of the dielectric layer.

Implementations of semiconductor devices may include one, all, or any of the following:

The second electrode of the first capacitor may include a first layer including aluminum (Al) and a second layer including titanium nitride (TiN).

The second capacitor may include a first electrode including Al and TiN and a second electrode including TiN.

The semiconductor device may further include a layer of tantalum nitride (TaN) between the first electrode and the dielectric layer of each of the first capacitor and the second capacitor.

The second capacitor may further include the dielectric layer covering one or more edges of the second electrode.

The first electrode and the second electrode may each be included in an interlayer dielectric.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a cross sectional view of an implementation of a substrate including an implementation of an electrode plate;

FIG. 2 is a cross sectional view of an implementation of the substrate from FIG. 1 after etching the implementation of the electrode plate;

FIG. 3 is a cross sectional view of an implementation of the substrate of FIG. 1 with an implementation of vias coupled to a metal plate;

FIG. 4 is a cross sectional view of an implementation of a substrate including an implementation of a first electrode plate and implementations of two second electrode plates thereof;

FIG. 5 is a cross sectional view of an implementation of a substrate including an implementation of a first electrode plate after etching;

FIG. 6 is a cross sectional view of an implementation of a semiconductor device including two capacitors;

FIG. 7 is a cross sectional view of an implementation of a semiconductor device;

FIG. 8 is a cross sectional view of an implementation of a substrate including an implementation of a first electrode, a second electrode, and an interlayer dielectric;

FIG. 9 is a cross sectional view of an implementation of a substrate including an implementation of a first electrode, a second electrode, and an interlayer dielectric after etching of the first electrode and the interlayer dielectric;

FIG. 10 is a cross sectional view of an implementation of a semiconductor device;

FIG. 11 is a cross sectional view of an implementation of a semiconductor device with a first electrode coupled to vias.

FIG. 12 is a cross sectional view of the implementation of the semiconductor device of FIG. 11 with a dielectric layer and a second electrode coupled to the first electrode;

FIG. 13 is a cross sectional view of the implementation of the semiconductor device of FIG. 12 with a metal plate coupled over the second electrode;

FIG. 14 is a cross sectional view of an implementation of a semiconductor device with a first electrode including tapered edges coupled to vias.

FIG. 15 is a cross sectional view of the implementation of the semiconductor device of FIG. 14 with a dielectric layer and a second electrode coupled over the first electrode;

FIG. 16 is a cross sectional view of the implementation of the semiconductor device of FIG. 15 with a metal plate coupled over the second electrode;

FIG. 17 is a cross section view of an implementation of a semiconductor device having a tantalum nitride and titanium nitride layer on a first electrode; and

FIG. 18 is a graph illustrating lower capacitor leakage with a tantalum nitride layer.

### DESCRIPTION

This disclosure, its aspects and implementations, are not limited to the specific components, assembly procedures or method elements disclosed herein. Many additional components, assembly procedures and/or method elements known in the art consistent with the intended metal insulator metal (MIM) capacitors will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such metal insulator metal (MIM) capacitors, and implementing components and methods, consistent with the intended operation and methods.

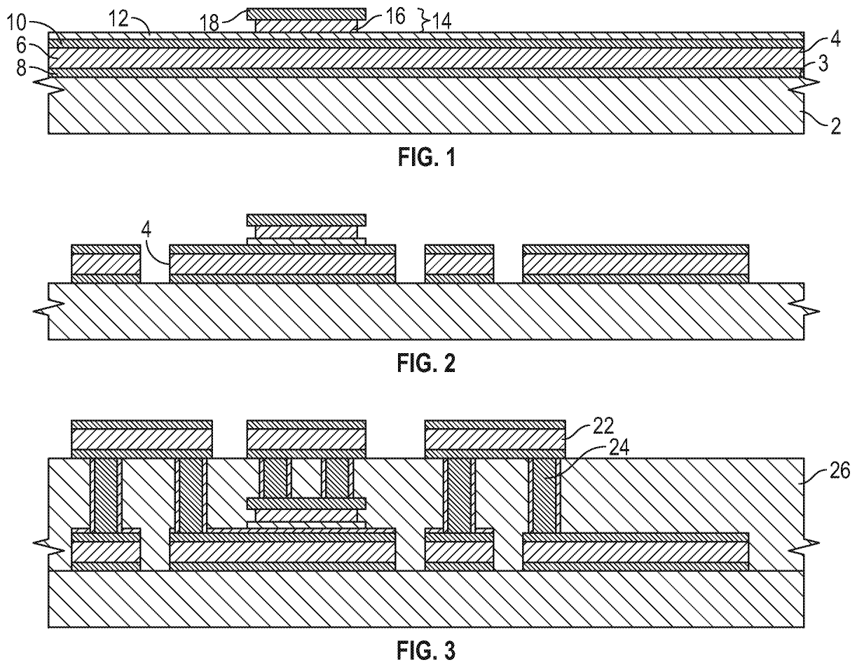

Referring to FIG. 1-3, an implementation of a metal insulator metal (MIM) capacitor at various points in an implementation of a method of forming a MIM capacitor is illustrated. In FIG. 1, a substrate 2 is illustrated having a first plate 4 coupled to a second side 3 of the substrate. In various implementations, the first plate may include aluminum (Al) 6 coupled between two layers 8 and 10 of titanium nitride (TiN). The method may include coupling a dielectric layer 12 on a second side of the first plate 4. The dielectric layer may have a high dielectric constant (HiK) meaning the dielectric constant is higher than the dielectric constant of silicon dioxide (SiO₂). In various implementations, the dielectric layer may include aluminum oxide, hafnium oxide (HfO₂), and zirconium oxide (ZrO₂). In some implementations, the dielectric layer may include an aluminum oxide (Al₂O₃) having a thickness of 3.7 nm and a silicon dioxide (SiO₂) layer of 1.9 nm. A second electrode 14 may then be coupled to the dielectric layer. The second electrode 14 may include a first layer 16 including Al and a second layer 18 including TiN. The first layer of the second electrode may then be etched to have a smaller width than the second layer. The first layer may be wet etched. In various implementations of wet etching, buffered hydrofluoric acid (BHF) or dilute HF (DHF) may be used. In other implementations, other suitable acids for etching the material of the layer may be used for the wet etching process. The smaller width of the first layer of the second electrode may protect against voltage leakage at the perimeter of the first electrode. Referring to FIG. 2, the first electrode/first plate 4 may be etched to mechanically and electrically separate portions of the device. The method may also include mechanically and electrically coupling the capacitor to an additional metal plate 22 layer through vias 24. The electrodes and vias may then be encapsulated through an interlayer dielectric layer 26. In various implementations, the interlayer dielectric layer may include SiO₂.

Implementations of capacitors described herein may be used in image sensors. Image sensors with high dynamic ranges may utilize at least one high capacitance density capacitor per pixel. In some implementations, the image sensors will have two high capacitance density capacitors. Image sensors may also be used with global shutters and have the same requirements for at least one high capacitance density capacitor per pixel. In various implementations, the capacitors may be metal insulator metal (MIM) capacitors. A capacitance density of 25 fF/um² may be preferred/desired in various implementations.

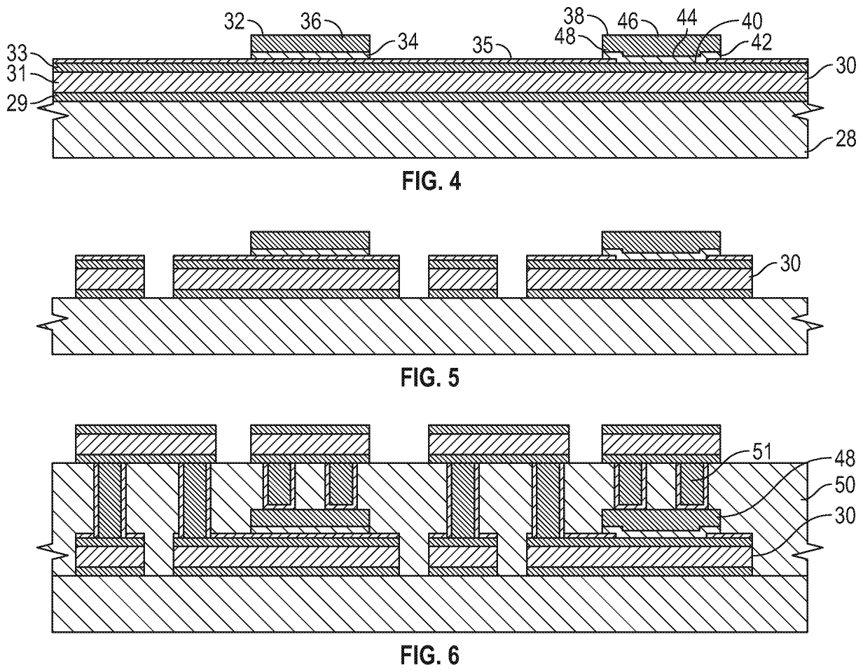

Referring to FIGS. 4-6, an implementation of a MIM capacitor at various stages of an implementation of a method of forming a MIM capacitor is illustrated. Referring to FIG. 4, the method includes providing a substrate 28 having a first side and a second side. The method may include patterning the second side of the substrate 28. Various methods of photolithography may be employed in the various method implementations described herein to accomplish the patterning operation. In some implementations, the substrate may include silicon dioxide. The device includes a MIM layer 30 coupled to a second side of the substrate 28 as the first electrode in the device. In this particular implementation, the MIM layer 30 includes a first layer of TiN 29, a second layer of Al 31, and a third layer of TiN 33. The third layer 33 of the MIM may be patterned with a layer of silicon nitride (SiN) 35. On the layer of SiN two or more capacitors may be formed. A first capacitor 32 may include the MIM acting as the first electrode 30, a dielectric layer 34 on the MIM, and a second electrode 36 included on the dielectric layer 34. The dielectric layer may include a material having a high dielectric constant (HiK) such as aluminum oxide, hafnium oxide (HfO2), zirconium oxide (ZrO2), or any other dielectric materials mentioned in this document with a dielectric constant higher than that of silicon dioxide.

As illustrated, a second capacitor 38 may be formed by patterning an opening 40 into the layer of SiN 29. A HiK dielectric layer 42 may be coupled within and around the opening in the SiN layer 35. As illustrated, the dielectric layer 42 may include a recess 44. A second electrode 46 of the second capacitor 48 may be coupled within the recess 44 of the dielectric layer 42. The first capacitor and the second capacitor may be formed simultaneously through patterning and etching of the materials described. Referring to FIG. 5, the first electrode 30 may be etched to mechanically and electrically separate portions of the device. As illustrated in FIG. 6, the electrodes 30 and 46 of the second capacitor 48 and vias 51 may be encapsulated in an interlayer dielectric layer 50 forming a semiconductor device. In various implementations, the interlayer dielectric layer may include SiO₂.

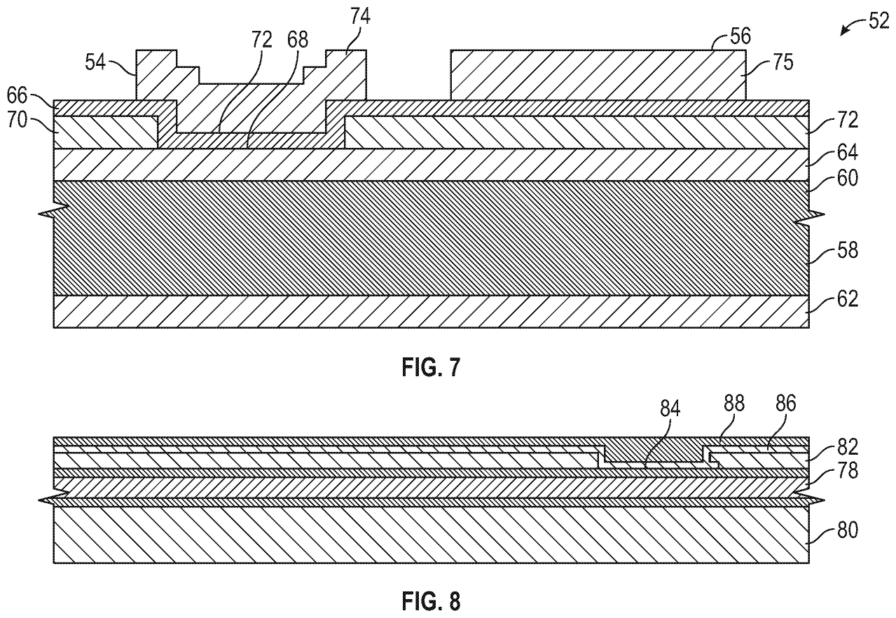

Referring to FIG. 7, a more detailed drawing of FIG. 6 is illustrated. The device include two capacitors, one of which is a high dielectric constant (HiK) metal insulator metal (MIM) capacitor 54 and other is a hybrid MIM capacitor 56. The device includes a first layer 58 including Al 60 having a layer of TiN on a first side 62 and a second side 64 of the Al. The HiK MIM capacitor 54 includes a layer of aluminum oxide 66 within an opening 68 in a silicon nitride layer 70. The opening 68 may have a depth of about 10 to about 50 nm. In some implementations, the depth of the opening may be smaller or larger. The opening/cavity may be generated during the formation of the semiconductor device. The aluminum oxide layer 66 includes a recess 72. In the recess 72 a TiN electrode 74 is coupled to the layer of aluminum oxide 66. The HiK MIM capacitor 54 may provide a capacity density of about 6 fF/μm². The hybrid MIM capacitor 56 includes a layer of SiN 72 coupled to the TiN on the second side 64 of the Al. A layer of aluminum oxide 66 is coupled to the SiN and a second electrode 75 is coupled to the aluminum oxide. In this particular implementation, the second electrode 75 in each of HiK MIM capacitor and the hybrid MIM capacitor include TiN. In other implementations, the second electrode may be formed of other materials. The hybrid MIM capacitor may provide linearity to the device having a capacitor density of 2 fF/μm².

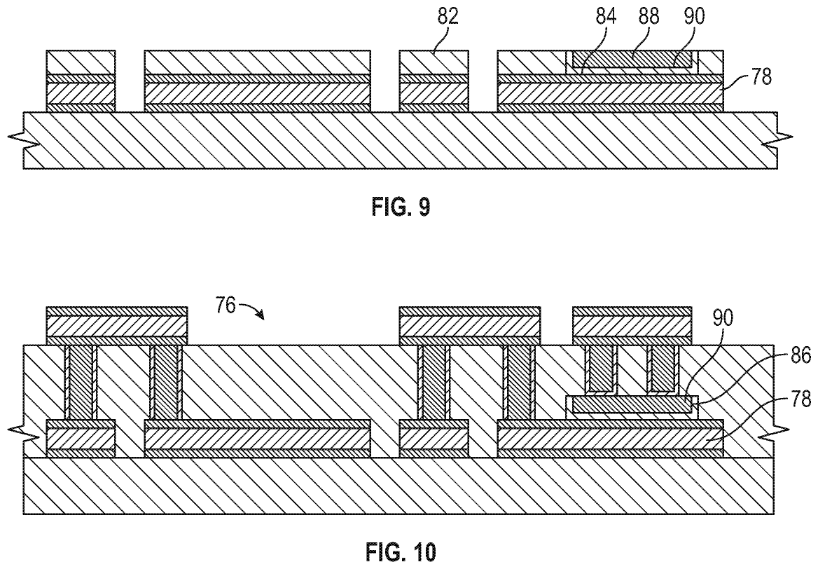

Referring to FIGS. 8-10, another MIM capacitor at various stages of an implementation of method for forming a MIM capacitor is illustrated. Referring to FIG. 8, the device includes a metal plate 78 coupled to a substrate 80. The metal plate 78 may include aluminum. Formed on the metal plate 78 is an interlayer dielectric material 82 including a cavity 84. The interlayer dielectric material 82 may include silicon dioxide. A layer 86 of dielectric material having a high dielectric constant (HiK) is coupled to the interlayer dielectric material 82 and a metal layer 88 is formed on the HiK layer 86. Chemical mechanical planarization (CMP) is then performed on the metal layer 88 and the HiK layer 82 to remove the portions not within the cavity 84 of the interlayer dielectric material 82. In various implementations, other methods, such as, by non-limiting example, dry etching or wet etching may be used to remove excess dielectric material. As illustrated in FIG. 9, the metal plate 78 is etched and a second electrode 90 is formed from the metal layer 88 is within the cavity 84 in the silicon dioxide layer 82. In FIG. 10, the device with vias and additional structure added is illustrated. As illustrated, the semiconductor device 76 has a first electrode 78 coupled with a second electrode 90, where the second electrode includes a dielectric material 86 covering one or more edges of the second electrode. The dielectric material 86 covering one or more edges of the second electrode 90 may prevent perimeter leakage. The capacitor formed with the first electrode 78 and the second electrode 90 may be a low voltage capacitor.

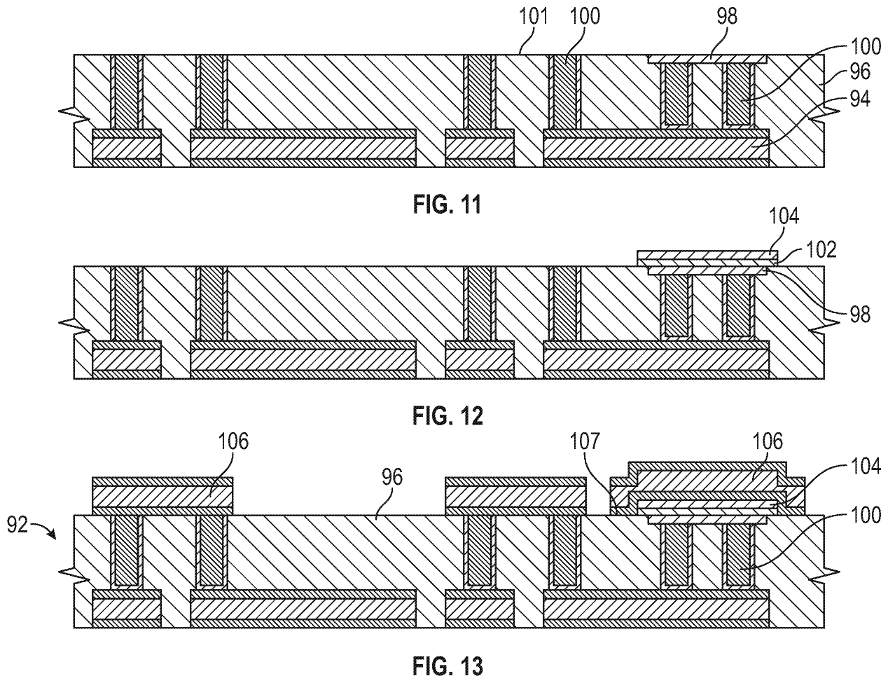

Referring to FIG. 11-13, a MIM capacitor at various points in an implementation of a method of forming a MIM capacitor 92 is illustrated. Referring to FIG. 11, the device includes a metal plate 94 encapsulated in an interlayer dielectric material 96. The metal plate 94 may have a damascene structure or be formed using a damascene process. The interlayer dielectric material 96 may include vias 100 extending from the metal plate to a second edge 101 of the interlayer dielectric material 96. A first electrode 98 is formed on two of the vias 100. The first electrode 98 may include TiN. Referring to FIG. 12, a dielectric material 102 is formed on the first electrode 98 which may be HiK material like any disclosed in this document. A second electrode 104 is then deposited on the dielectric material 102. A second metal plate 106 is then coupled to the vias 100 over the interlayer dielectric material 96. The second metal plate 106 is then formed around the edges of the second electrode 104. Referring to FIG. 13, a device having a damascene bottom electrode formed on top of vias and a top electrode formed under the Al wiring layer 107 is illustrated.

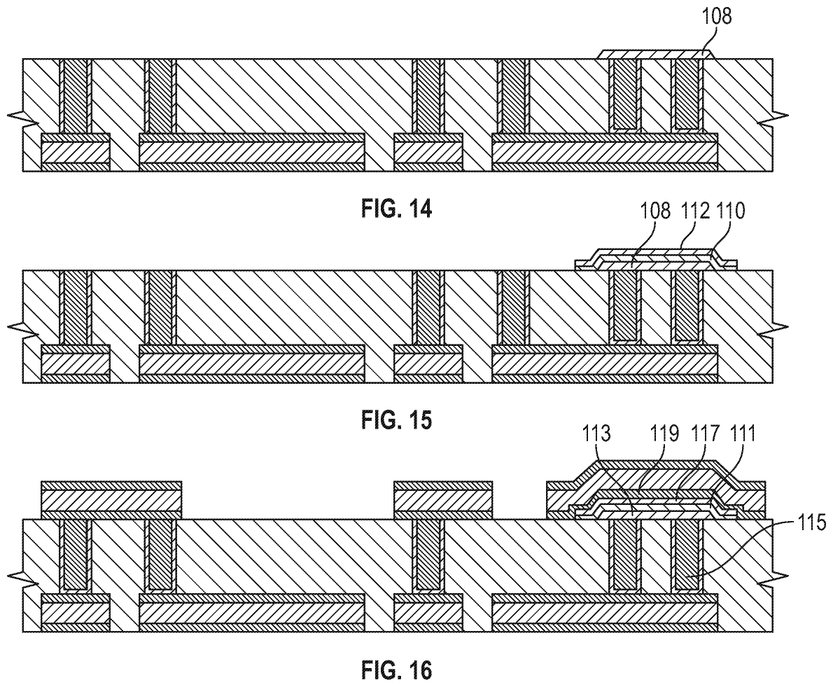

Referring to FIG. 14-16, a MIM capacitor at various points in a similar method implementation to the method illustrated in FIGS. 11-13. In FIG. 14, the first electrode 108 has a tapered/chamfered/spaced shape. Referring to FIG. 15, a dielectric layer 110 and a top electrode 112 are then formed over and around the tapered first electrode 108 to cover the sides of the first electrode 108. The two layers over the first electrode may protect against leakage from perimeter of the bottom electrode. Referring to FIG. 16, a MIM capacitor 111 with a bottom electrode 113 formed using reactive ion etch (RIE) is illustrated on top of vias 115, and a top electrode 117 formed under the Al wiring layer 119 is illustrated. The device illustrated in FIG. 16 may be manufactured using a method illustrated in FIGS. 14-15 following additional processing steps.

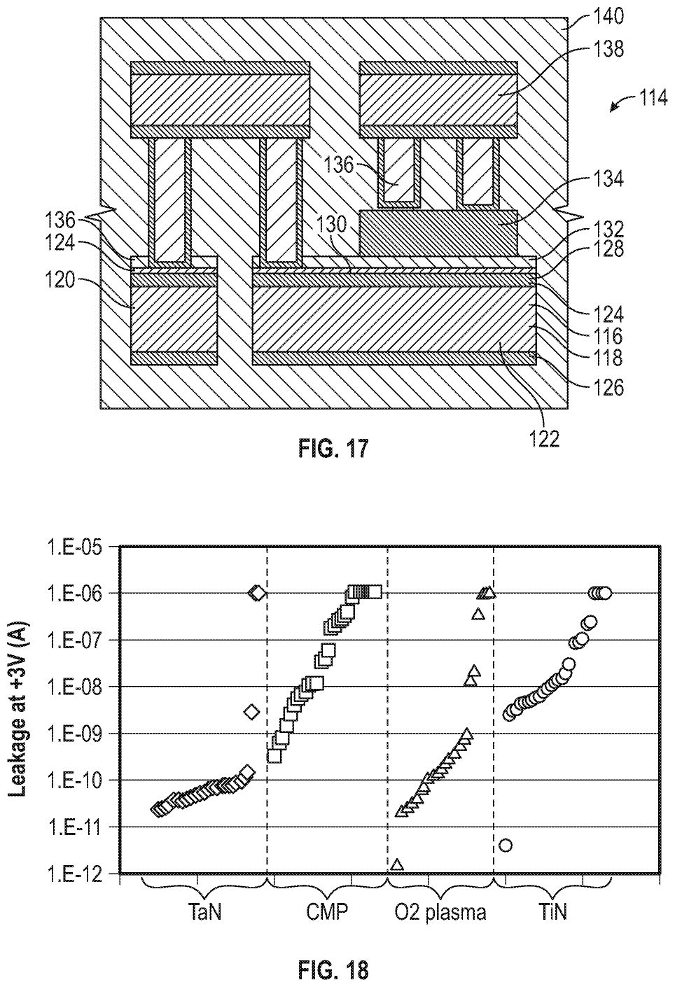

Referring to FIG. 17, an implementation of a semiconductor device 114 is illustrated. The device 114 includes a first electrode 116 having a first portion 118 and a second portion 120. The first electrode 116 includes an aluminum plate 122 having a TiN 124 coating on a first side 126 and a second side 128 of the plate 122. The first portion 118 includes a layer of TaN 130 over the first electrode 116 and a layer of aluminum oxide 132 over the TaN layer 130. The TaN layer 130 may have a thickness of about 5 nm to about 1100 nm. The second portion 120 of the first electrode 116 includes only a layer of TiN 124 over the first electrode 116 and a layer of aluminum oxide 132 over the TiN. The layer of TiN can have a thickness between about 0 nm to about 100 nm. On the first portion 118 of the first electrode 116 a second electrode 134 is coupled to the layer of aluminum oxide 132. The second electrode 134 may include TiN, TaN, or a combination of TaN/TiN. The first portion 118 and the second portion 120 of first electrode 116 are electrically coupled through vias 136 and a metal plate 138 is coupled to the vias 136. The device is encapsulated in an interlayer dielectric material 140. The dielectric material may include silicon dioxide. In various implementations, the dielectric materials may include SiN or high dielectric constant materials.

Referring to FIG. 18, a graph illustrates the leakage current of different implementations of the device in FIG. 17. All devices have the same capacitance but the leakage current is much different depending on the formation process for the bottom electrode of the MIM capacitor. The lowest leakage current is illustrated with diamonds as observed in a device having a combination of a layer of TiN/TaN between the first electrode and the dielectric layer. The squares illustrate a device having a layer of TiN applied through chemical mechanical polishing (CMP). The triangles illustrated a device having a layer of TiN treated with/exposed to an oxygen (O₂) plasma. The circles illustrate a device with only TiN on the second side of the first electrode of the device. Typically a MIM capacitor is formed with a standard TiN electrode for the bottom electrode. The leakage current behavior in FIG. 18 illustrates that relatively small changes in the bottom electrode formation can be very beneficial for reducing the leakage current of the capacitor, thereby reducing power consumption of the device and improving reliability.

In places where the description above refers to particular implementations of metal insulator metal (MIM) capacitors and implementing components, sub-components, methods and sub-methods, it should be readily apparent that a number of modifications may be made without departing from the spirit thereof and that these implementations, implementing components, sub-components, methods and sub-methods may be applied to other metal insulator metal (MIM) capacitors.

What is claimed is:

1. A capacitor comprising:
a first electrode, the first electrode comprising a first side and a second side;
a silicon nitride (SiN) layer comprised on the second side of the first electrode wherein the layer comprises an opening therein;
a dielectric layer comprised within the opening of the SiN layer, the dielectric layer comprising a recess; and
a second electrode comprising a first side and a second side, a first side of the second electrode comprised within the recess of the dielectric layer.

2. The capacitor of claim 1, wherein the dielectric layer comprises aluminum oxide.

3. The capacitor of claim 1, wherein the second electrode comprises titanium nitride (TiN).

4. The capacitor of claim 1, further comprising a layer of tantalum nitride (TaN) between the first electrode and the dielectric layer.

5. The capacitor of claim 1, wherein the first electrode comprises TiN on Al.

6. The capacitor of claim 1, wherein the second electrode comprises a first layer of Al and a second layer of TiN.

7. The capacitor of claim 1, wherein the first electrode is coupled to two or more vias.

8. The capacitor of claim 1, wherein both the first electrode and the second electrode comprise TiN.

9. The capacitor of claim 1, further comprising wherein the dielectric layer covers one or more edges of the second electrode.

10. A capacitor comprising:
a substrate comprising a first side and a second side:
a first electrode comprised on the second side of the substrate;
a silicon nitride layer comprising an etch stop;
a dielectric layer comprised in and around the etch stop; and
a second electrode over the dielectric layer;
wherein the capacitor is encapsulated in an interlayer dielectric material.

11. The capacitor of claim 10, wherein the dielectric layer comprises aluminum oxide.

12. The capacitor of claim 10, wherein the second electrode comprises titanium nitride (TiN).

13. The capacitor of claim 10, further comprising a layer of tantalum nitride (TaN) between the first electrode and the dielectric layer.

14. The capacitor of claim 10, further comprising wherein the dielectric layer covers one or more edges of the second electrode.

15. A semiconductor device comprising:
a substrate comprising a first side and a second side,
a first capacitor comprised on the second side of the substrate, the first capacitor comprising:
a first electrode comprised on the second side of the substrate, the first electrode having a first side and a second side:
a silicon nitride (SiN) film comprised on the second side of the first electrode;
a dielectric layer comprised on the SiN film; and
a second electrode comprised on the dielectric layer;
a second capacitor comprised on the second side of the substrate, the second electrode comprising:
a first electrode, the first electrode comprising a first side and a second side;
a silicon nitride (SiN) layer comprised on the second side of the first electrode wherein the layer comprises an opening therein;
a dielectric layer comprised within the opening of the SiN layer, the dielectric layer comprising a recess; and
a second electrode comprising a first side and a second side, a first side of the second electrode comprised within the recess of the dielectric layer.

16. The semiconductor device of claim 15, wherein the second electrode of the first capacitor comprises a first layer comprising aluminum (Al) and a second layer comprising titanium nitride (TiN).

17. The semiconductor device of claim 15, wherein the second capacitor comprises the first electrode comprising Al and TiN and the second electrode comprising TiN.

18. The semiconductor device of claim 15, further comprising a layer of tantalum nitride (TaN) between the first electrode and the dielectric layer of each of the first capacitor and the second capacitor.

19. The semiconductor device of claim 15, wherein the second capacitor further comprises wherein the dielectric layer covers one or more edges of the second electrode.

20. The semiconductor device of claim 15, wherein the first electrode and the second electrode are each comprised in an interlayer dielectric
